(19) United States
(12) Patent Application Publication
(10) Pub. No.: US 2025/0222492 A1
(43) Pub. Date: Jul. 10, 2025

(54) METHOD FOR CLEANING AN APPARATUS FOR A TIN COMPOUND AND THE CLEANED APPARATUS OBTAINED THEREBY

(71) Applicants: Mitsubishi Chemical Corporation, Tokyo (JP); Gelest, Inc., Morrisville, PA (US)

(72) Inventors: Koki ISHII, Tokyo (JP); Hiroshi FUKUI, Tokyo (JP); Li YANG, Belle Mead, NJ (US)

(21) Appl. No.: 19/000,069

(22) Filed: Dec. 23, 2024

Related U.S. Application Data
(60) Provisional application No. 63/617,788, filed on Jan. 5, 2024.

(51) Int. Cl. B08B 3/08; C11D 7/06; C11D 7/08; C11D 7/50; H01L 21/027

(52) U.S. Cl. CPC B08B 3/08; C11D 7/06; C11D 7/08; C11D 7/5004; B08B 2220/00; C11D 2111/14; H01L 21/0274

(57) ABSTRACT

A method for efficiently and safely cleaning an apparatus for a tin compound and a highly purified apparatus for a tin compound are provided. A method of cleaning an apparatus that has been in contact with a tin compound having formula (1) includes at least steps (A) to (C) in this order:
(A) a step of cleaning the apparatus with a non-protonic solvent,
(B) a step of cleaning the apparatus with an acidic aqueous solution and/or alkaline aqueous solution, and
(C) a step of cleaning the apparatus with ultrapure water having a resistivity of 17 MΩ·cm at 25° C.

RₚSₙXₘ (1)

R is a hydrocarbon group, p is an integer of 0 to 3, X is a hydrolyzable substituent, and m=4-p.

### CROSS-REFERENCE TO RELATED APPLICATION

This application claims priority to co-pending U.S. Provisional Application No. 63/617,788, filed Jan. 5, 2024, the disclosure of which is herein incorporated by reference in its entirety.

### SUMMARY OF THE INVENTION

### Technical Field

The present invention relates to a method for cleaning an apparatus for a tin compound and the cleaned apparatus obtained thereby, and more particularly to a method for efficiently and safely cleaning an apparatus for a tin compound and the highly purified apparatus obtained thereby.

### BACKGROUND ART

In recent years, with the paradigm shift towards a highly information-oriented society, there is a demand for handling larger amounts of information at higher speeds and with greater precision. Semiconductor technology, such as integrated circuits using semiconductors, is advancing remarkably day by day.

Conventional chemically amplified resists (CARs) have potential drawbacks when used in EUV lithography, particularly due to their low absorption coefficients in the EUV region, which can lead to diffusion blurring of photoactive species or line edge roughness. Therefore, there remains a need for improved EUV photoresist materials with characteristics such as thinner thickness, better absorbance, and superior etching resistance.

For this reason, liquid CVD materials such as organotin compounds have recently begun to be used as resists particularly suitable for EUV applications. To achieve high-quality film formation, extremely high-purity materials are required. Therefore, before using tin compounds as CVD materials, impurities such as water, residual solvents used in synthesis, and metal impurities must be removed by distillation or other means (Patent Document 1), and the introduction of impurities must be avoided as much as possible.

### Prior Art Documents

[Patent Document 1] Patent Publication No. JP2020-530199

### Problem to be Solved by the Invention

However, tin compounds react with oxygen and water to form stannoxane compounds, which may adhere to and remain on an apparatus for a tin compound, becoming impurities in subsequent synthesis or storage, or potentially causing a decrease in the purity of tin compounds.

Therefore, against this background, the present invention aims to discover an efficient and safe method for cleaning an apparatus for a tin compound and to provide a highly purified apparatus for a tin compound.

### Means for Solving the Problem

As a result of intensive research to solve these problems, the inventors have discovered a method for efficiently and safely cleaning an apparatus for a tin compound by employing a special cleaning process when cleaning equipment that has been in contact with specific tin compounds and has impurities adhered to it.

That is, the present invention has the following aspects:

[1]

A method for cleaning an apparatus that has been in contact with a tin compound having formula (1), the method comprising at least steps (A) to (C), wherein step (B) is performed after step (A), and step (C) is performed after step (B):
(A) a step of cleaning the apparatus with a non-protic solvent,
(B) a step of cleaning the apparatus with an acidic aqueous solution and/or an alkaline aqueous solution, and
(C) a step of cleaning the apparatus with ultrapure water having a resistivity value of 17 MΩ·cm at 25° C.,

RₚSnXₘ (1)

wherein R is a hydrocarbon group, p is an integer from 0 to 3, X is a hydrolyzable substituent, and m=4-p.
[2]

The method for cleaning an apparatus according to [1], wherein the step (A) is followed by performing the step (B) sequentially without any other cleaning steps in between.

[3]

The method of cleaning the apparatus for a tin compound described in [1] or [2], wherein after the above step (A), a drying step is performed, and then the above step (B) is performed sequentially.

[4]

The method of cleaning the apparatus for a tin compound described in any one of [1] to [3], wherein after the above step (A), a step of cleaning with alcohol and the drying step are performed, and then the above step (B) is performed continuously.

[5]

The method of cleaning the apparatus for a tin compound described in any one of [1] to [4], wherein the above non-protonic solvent contains at least one solvent selected from the group consisting of aromatic hydrocarbons, aliphatic hydrocarbons, esters, and ethers.

[6]

The method of cleaning the apparatus for a tin compound described in any one of [1] to [5], wherein the above acidic aqueous solution is a 3 to 30% by mass nitric acid aqueous solution.

[7]

The method of cleaning the apparatus for a tin compound described in any one of [1] to [6], wherein the pH of the above alkaline aqueous solution is 11.5 or less.

[8]

The method of cleaning the apparatus for a tin compound described in any one of [1] to [7], wherein the above alkaline aqueous solution is at least one aqueous solution selected from the group consisting of phosphates, sodium hydroxide, and potassium hydroxide.

[9]

The method of cleaning the apparatus for a tin compound described in [8], wherein the concentration of sodium hydroxide and/or potassium hydroxide is 0.5 to 2% by mass.

[10]

The method of cleaning the apparatus for a tin compound described in any one of [1] to [9], wherein after the above step (C), the drying step is performed.

[11]

The method of cleaning the apparatus for a tin compound described in any one of [1] to [10], wherein p in the above general formula (1) is 0 or 1.

[12]

The method of cleaning the apparatus for a tin compound described in any one of [1] to [11], wherein the tin compound represented by the above general formula (1) is at least one selected from the group consisting of t-butyltris(dimethylamino)tin, n-butyltris(dimethylamino)tin, t-butyltris(diethylamino)tin, di-t-butylbis(dimethylamino)tin, sec-butyltris(dimethylamino)tin, n-pentyltris(dimethylamino)tin, isobutyltris(dimethylamino)tin, isopropyltris(dimethylamino)tin, t-butyltri-t-butoxytin, n-butyltri-t-butoxytin, isopropyltri-t-butoxytin, isopropyltri-t-amyloxytin, t-butyltri-t-amyloxytin, tetra-t-butoxytin, tetrakis(dimethylamino)tin, 1-methyl-1-cyclopentyltris(dimethylamino) tin, and 1-methyl-1-cyclopentyltri-t-butoxy tin.

[13]

The apparatus for a tin compound that has been in contact with the compound represented by the above general formula (1) and has been cleaned by the cleaning method described in any one of [1] to [12].

[14]

The apparatus for a tin compound described in [13] is a tin compound storage container.

[15]

The apparatus for a tin compound described in [13], wherein when ultrapure water having a specific resistivity of 17 MΩ·cm at 25° C. is filled into the apparatus and left at 25° C. for 1 hour, a content of each metal element chromium, iron, magnesium, nickel, sodium, and potassium, is 1.5 mass ppb or less.

[16]

The apparatus for a tin compound obtained by cleaning an apparatus that has been in contact with a tin compound having formula (1) described in [13], wherein when the apparatus is filled with ultrapure water having a specific resistivity of 17 MΩ·cm at 25° C. and left at 25° C. for 1 hour, an increase in the amount of halogen ions in the water is 100 mass ppb or less, and an increase in the amount of particles with a particle size of 0.5 μm or more is 100/mL or less.

[17]

The apparatus for a tin compound described in [13], wherein when the tin compound having formula (1) is placed in the apparatus, sealed under an inert gas atmosphere, and stored at 25° C. for 1 month, the purity of the tin compound decreases by 0.1 mass % or less.

[18]

The apparatus for a tin compound described in [13], wherein when the apparatus is vacuum-dried and then filled with helium at 34.5 kPa, the valve seat leakage amount measured by a helium detection apparatus is 5×10⁻⁹ Pa·m³/s or less.

[19]

The apparatus for a tin compound described in any one of [15]-[17], which is a tin compound storage container.

[20]

A pattern forming method for semiconductors, including a step of depositing a tin compound having formula (1) on a substrate using an apparatus for a tin compound that has been in contact with the tin compound having formula (1) to obtain a thin film, a step of exposing the thin film to radiation, and a step of developing the exposed thin film, wherein the apparatus for a tin compound is a tin compound storage container in which when ultrapure water having a specific resistivity of 17 MΩ·cm at 25° C. is filled into the apparatus and left at 25° C. for 1 hour, the content of each metal element Cr, Fe, Mg, Ni, Na, and K is 1.5 mass ppb or less:

[001]RₚSₙXₘ (1)

wherein R is a hydrocarbon group, p is an integer of 1 to 3, X is a hydrolyzable substituent, and m=4-p.
[21]

A method of manufacturing a semiconductor, the method comprising performing the pattern forming method described in [20].

### Effect of the Invention

The method for cleaning an apparatus for a tin compound according to the present disclosure makes it possible to efficiently and safely clean the apparatus. Furthermore, the cleaned apparatus obtained by the method according to the present disclosure is highly purified, and the occurrence of impurities is suppressed, resulting in an apparatus that does not cause a decrease in the purity of the tin compound.

### EMBODIMENT FOR CARRYING OUT THE INVENTION

The present invention will be described below with reference to examples of embodiments for carrying out the present invention. However, the present invention is not limited to the following embodiments.

Unless otherwise stated, any numerical value is to be understood as being modified in all instances by the term “about.” Thus, a numerical value typically includes ±10% of the recited value. For example, the recitation of a temperature such as “10° C.” or “about 10° C.” includes 9° C. and 11° C. and all temperatures there between.

All numerical ranges expressed in this disclosure expressly encompass all possible subranges, all individual numerical values within that range, including integers within such ranges and fractions and decimal amounts of the values unless the context clearly indicates otherwise.

Note that, in the present invention, when expressing “α to β” (α and β are arbitrary numbers), unless otherwise specified, it includes the meaning of “α or more and β or less” together with the meaning of “preferably larger than α” or “preferably smaller than β”. Also, when expressing “α or more” (α is an arbitrary number) or “β or less” (β is an arbitrary number), it includes the meaning of “preferably larger than α” or “preferably smaller than β”. Furthermore, “γ and/or δ (γ, δ are arbitrary components)” means that it means at least one of γ and δ, and means three types of γ only, δ only, and γ and δ.

One embodiment of the method of cleaning the apparatus for a tin compound of the present invention (hereinafter sometimes referred to as “the present cleaning method”) is a method of cleaning an apparatus that has been in contact with a tin compound having formula (1), comprising at least the following steps (A) to (C) in this order.
(A) a step of cleaning the apparatus with a non-protonic solvent,
(B) a step of cleaning the apparatus with an acidic aqueous solution and/or alkaline aqueous solution, and
(C) a step of cleaning the apparatus with ultrapure water having a specific resistivity of 17 MΩ·cm at 25° C.;

RₚSnXₘ (1)

In Formula (1), R is a hydrocarbon group, p is an integer of 0 to 3, X is a hydrolyzable substituent, and m=4-p.

Another embodiment of the cleaning method is a cleaning method in which, after the above step (A), a step of cleaning with alcohol and a drying step are performed, and then the above step (B) and the above step (C) are performed.

### <Specific Tin Compound>

The present cleaning method is applied to an apparatus that comes into contact with a specific tin compound. The tin compound of the present invention means a tin compound represented by the general formula “RₚSnXₘ”.

In the above formula, “R” is a hydrocarbon group, preferably a hydrocarbon group having 1 to 30 carbon atoms, more preferably a hydrocarbon group having 1 to 15 carbon atoms, more preferably a hydrocarbon group having 1 to 10 carbon atoms, and further preferably a hydrocarbon group having 2 to 6 carbon atoms. Examples of saturated hydrocarbon groups include a methyl group, ethyl group, n-propyl group, isopropyl group, n-butyl group, isobutyl group, t-butyl group, 1-methylcyclopentyl group, etc. and examples of unsaturated hydrocarbon groups include a vinyl group, 2-propenyl group, etc. Examples of aromatic hydrocarbon groups include a phenyl group, tolyl group, benzyl group, phenethyl group, etc.

Also, in the above formula, “X” means a hydrolyzable substituent, such as halogen, an amino group, alkoxy group (—OR′), alkynide (R′C≡C), azide (N₃⁻), dialkylamino group (—NR′₂) (—NR′R″), N-alkyl-N-alkoxycarbonylamino group (—N(R′)C(O)R′)(—N(R′)C(O)R″)(—N(R″)C(O)R′), alkoxycarbonyl group (—OCOR′), N-alkylcarbamoyl group (—N(H)C(O)R′), etc. R′ and R″ are each independently a hydrocarbon group having 1 to 10 carbon atoms. Among them, X is preferably a dialkylamino group, an alkoxy group, an N-alkyl-N-alkoxycarbonylamino group, a halogen, or an alkoxycarbonyl group, more preferably a dialkylamino group or an alkoxy group, and particularly preferably a dialkylamino group (—NR′₂) or an alkoxy group (—OR′).

In the above formula, “p” is an integer of 0 to 3, “m” is an integer of 1 to 4, and m=4-p. p is preferably 0 or 1. When p is 0 or 1, three or four hydroxyl groups are introduced when the hydrolyzable group is hydrolyzed, and these are dehydrated and condensed to form a compound having a network structure of Sn—O—Sn bond (stannoxane), which is expected to be applied to the present cleaning method because it is difficult to dissolve in ordinary solvents.

Among the above tin compounds, a tin compound represented by the following general formula (2) (“monoalkyltin compound”) is particularly preferable.

RSnX₃ (2)

In formula (2), R is a hydrocarbon group having 1 to 30 carbon atoms, and X represents a hydrolyzable substituent.

Examples of compounds represented by formula (2) include t-butyltris(dimethylamino)tin, n-butyltris(dimethylamino)tin, t-butyltris(diethylamino)tin, sec-butyltris(dimethylamino)tin, n-pentyltris(dimethylamino)tin, isobutyltris(dimethylamino)tin, isopropyltris(dimethylamino)tin, t-butyltri-t-butoxytin, n-butyltri-t-butoxytin, isopropyltri-t-butoxytin, isopropyltri-t-amyloxytin, t-butyltri-t-amyloxytin, 1-methyl-1-cyclopentyltris(dimethylamino) tin, 1-methyl-1-cyclopentyltri-t-butoxy tin, etc. These can be used alone or in combination of two or more.

The molecular weight of the above tin compound is usually 200 to 900. Considering that a certain vapor pressure is necessary when used for CVD, it is preferably 240 to 700, more preferably 260 to 600, and further preferably 280 to 500.

The above tin compound may be a single compound or a mixture of two or more kinds of compounds. When two or more kinds of tin compounds are mixed, it is preferable that the difference in molecular weight between the two kinds is 100 or less, because they can be volatilized simultaneously in the film-forming step by CVD, and it is more preferable that the difference is 50 or less, further preferably 30 or less, and particularly preferably 15 or less. It is also preferable that the mixture be a mixture of isomers having the same molecular weight for the same reason.

### <Apparatus for a Tin Compound>

The apparatus for a tin compound which is encompassed by the cleaning method described herein includes all devices or apparatuses that may come into contact with tin compounds in all industrial processes, such as synthesis, purification, storage (preservation), etc. of tin compounds.

Examples of the apparatus for a tin compound include, for example, a synthesis apparatus, a distillation purification apparatus, a filtration apparatus, a container for storage or preservation, a pipe connecting them, etc. The size of the apparatus, especially the size of the container, is usually 0.1 to 100 L, and from the viewpoint of easily exhibiting the effect of the present invention, it is preferably 0.1 to 30 L, and more preferably 0.5 to 10 L.

These apparatuses and pipes, etc. are usually manufactured with stainless steel, but may also be formed with nickel-based corrosion-resistant alloys such as Inconel. In order to improve the corrosion resistance inside the storage container and pipe, the inside of the container and pipe made of a metal material may be coated with a resin material such as a fluorine-based resin.

The above tin compound reacts with oxygen and water to generate impurities containing stannoxane compounds and low molecular weight oxidized tin compounds, which are the cause of scale. In order to efficiently remove such tin impurities from the apparatus, the present cleaning method includes the following cleaning steps.

<Step of Cleaning with Non-Protonic Solvent (A)>

In the step of cleaning with non-protonic solvent (non-protonic solvent cleaning step) (A), the apparatus is cleaned with a non-protonic solvent. The tin compound attached to the apparatus is dissolved in the non-protonic solvent and washed away. In addition, the stannoxane compound, etc. remaining in the apparatus is not dissolved in the non-protonic solvent, but in this non-protonic solvent cleaning step (A), it can be physically washed away.

When X in formula (1) has a highly hydrolyzable group such as a dialkylamino group, stannoxane compounds are easily generated, and there is a tendency that the cleaning effect of the present invention is more effectively obtained.

Appropriate non-protonic solvents that can be used include aromatic hydrocarbons such as toluene, xylene, benzene, etc.; aliphatic hydrocarbons such as hexane, heptane, octane, cyclohexane, methylcyclohexane, etc.; esters such as ethyl acetate, butyl acetate, butyl propionate, etc.; ethers such as diethyl ether, diisopropyl ether, methyl tertiary butyl ether, cyclopentyl methyl ether, tetrahydrofuran, 1,4-dioxane, etc. These solvents can be used alone or in combination of two or more.

The cleaning method is not particularly limited, and known cleaning methods for apparatuses used for compound synthesis and preservation can be appropriately adopted. For example, in the case of a synthesis apparatus, the method may involve attaching a recovery line after sending the reaction product to the next step, filling the reaction container with a non-protonic solvent, and recovering the non-protonic solvent from the recovery line. In addition, the apparatus can be disassembled and then washed with a non-protonic solvent, immersed, wiped, etc. When cleaning with spraying, the cleaning effect can be enhanced by spraying the non-protonic solvent together with air, and when filling the solvent into the apparatus or immersing the apparatus in the solvent, it is also possible to apply ultrasonic vibration. It is also possible to combine different cleaning methods.

The atmosphere during cleaning is preferably an environment with a reduced oxygen concentration or an inert gas atmosphere such as nitrogen, argon, helium, etc. in order to prevent the toxicity and flammability of decomposition products, such as amines generated during cleaning. In such an environment, for example, it is preferable to perform cleaning by setting the atmosphere in contact with the cleaning surface to a nitrogen atmosphere with an oxygen concentration of 0.1 volume % or less passed through a microfilter.

The number of cleaning times or cycles is not particularly limited, and it is possible to perform the cleaning only once, but in order to obtain sufficient cleaning effect, it is preferably performed 2 to 5 times. The cleaning temperature is also not particularly limited, and 0 to 70° C. is preferable, more preferably 0 to 50° C., and further preferably 10 to 30° C. The amount of non-protonic solvent used during cleaning is preferably 0.1 to 10.0 L/m² per unit area of the cleaned surface, more preferably 0.2 to 5.0 L/m², and further preferably 0.2 to 2.0 L/m².

In addition, it is also possible to clean by filling the container with a non-protonic solvent, and in this case, a non-protonic solvent having a volume almost the same as the capacity of the container is used.

A preferred embodiment of the present invention is to perform the step of cleaning with an acidic aqueous solution or an alkaline aqueous solution (step (B)) without going through the step of cleaning with alcohol after cleaning with a non-protonic solvent.

Non-protonic solvents and aqueous solutions have low solubility in each other and are insoluble. Therefore, it is generally considered that after cleaning with a non-protonic solvent, cleaning is attempted with an acidic or alkaline aqueous solution after once performing the step of cleaning with alcohol, described below, to completely remove the non-protonic solvent. However, when the tin compound remains in the container, it may be difficult to clean the container because the tin compound may become hydrolyzed and fixed or scaled by the slight amount of moisture accompanying the alcohol. In addition, if alcohol is used, there is a safety problem when trying to clean with nitric acid in a subsequent step. For example, a mixture of ethanol and nitric acid has potential explosiveness. This is generally caused by the generation of gas, but ethyl nitrate is also generated. Generally, nitric esters are explosive, and a solution of ethanol and nitric acid has a risk of explosion when the concentration of nitric acid is 10% by mass or more.

Of course, it is possible to clean with nitric acid after once cleaning with pure water after alcohol cleaning, or to clean with nitric acid after sufficient drying, but the process will be longer.

<Step of Cleaning with Alcohol>

In the present invention, it is preferable to perform the step of cleaning with an acidic aqueous solution and/or an alkaline aqueous solution (step (B)) without performing the step of cleaning with alcohol (alcohol cleaning step), but it is also possible to perform the alcohol cleaning step on the premise of adding a drying step or a step of cleaning with pure water after the alcohol cleaning step.

The alcohol is not particularly limited, and any of a fatty alcohol, a cyclic alcohol, and an aromatic alcohol can be used, and either a monoalcohol or a polyvalent alcohol can be used. Among them, a fatty monoalcohol is preferable, and methanol, ethanol, propanol, isopropanol, n-butanol, isobutanol, sec-butanol, t-butanol, 1-pentanol, 2-pentanol, 3-pentanol, cyclopentanol, 1-hexanol, 2-hexanol, 3-hexanol, 1-heptanol, 2-heptanol, 3-heptanol, 1-octanol, isooctanol, 2-ethylhexanol, isononyl alcohol, lauryl alcohol, etc. are appropriate alcohols. It is preferable that the number of carbon atoms of the alcohol is 1 to 12, more preferably 1 to 6, further preferably 1 to 3, and particularly preferably methanol. These alcohols may have a substituent such as an alkyl group. These alcohols can be used alone or in combination of two or more.

The cleaning method, the atmosphere during cleaning, the number of cleaning times, the cleaning temperature, the amount of cleaning liquid used, etc. are the same as in the non-protonic solvent cleaning step (A).

<Step of Cleaning with Acidic Aqueous Solution and/or Alkaline Aqueous Solution (B)>

As the step of cleaning with an acidic aqueous solution and/or an alkaline aqueous solution (B), for example, (i) the above step (A) may be followed by the above step (B) sequentially without any other steps in between, (ii) the above step (A) may be followed by a drying step, and then the above step (B) may be performed sequentially, (iii) the above step (A) may be followed by a step of cleaning with alcohol and a drying step, and then the above step (B) performed sequentially, etc. Among them, (i) is preferable in terms of simplification of the process and safety.

The above drying step can be performed by referring to the drying step after the ultrapure water cleaning step described below.

Also, as the step of cleaning with an acidic aqueous solution and/or an alkaline aqueous solution (B), at least one of the step of cleaning with an acidic aqueous solution (B-1) and the step of cleaning with an alkaline aqueous solution (B-2) may be used, but it is preferable to use either one of them in terms of simplification of the process.

[Step of Cleaning with Acidic Aqueous Solution (B-1)]

In the step of cleaning with an acidic aqueous solution, the apparatus is cleaned with an acidic aqueous solution. In this step (B-1), the residue that was not dissolved in the non-protonic solvent cleaning step (A) is used for dissolution, and, for example, is cleaned by dissolving the scale that is deposited on the joint part or dent of the apparatus and dissolves in acid. Since the mixing of alcohol and acid may involve the risk of explosion, when cleaning with alcohol, it is necessary to remove the alcohol by necessarily going through the drying step before cleaning with an acidic aqueous solution.

The acidic aqueous solution is not particularly limited as long as it is an acidic aqueous solution with a pH of less than 6, but preferably has a pH of 5 or less, and more preferably a pH of 1 or less. Among them, a nitric acid aqueous solution having oxidizing power is preferable, and a dilute nitric acid aqueous solution that does not form a passive state is more preferable. The concentration of nitric acid in the nitric acid aqueous solution is usually 3 to 30% by mass, preferably 5 to 25% by mass, and more preferably 8 to 20% by mass.

The cleaning method, the atmosphere during cleaning, the number of cleaning times, the cleaning temperature, the amount of cleaning liquid used, etc. are the same as in the non-protonic solvent cleaning step (A).

[Step of Cleaning with Alkaline Aqueous Solution (B-2)]

The tin compound supplied to the apparatus of the present embodiment is dissolved in both acidic aqueous solutions and alkaline aqueous solutions because tin is an amphoteric element. Therefore, it is preferable to perform cleaning with an alkaline aqueous solution instead of or in addition to cleaning with an acidic aqueous solution. Depending on the type of scale and impurities that occur, there are those that are easily dissolved in acids and those that are easily dissolved in alkalis, so if there is something that is not dissolved in an acidic aqueous solution, an alkaline aqueous solution is used. As the raw material of the alkaline aqueous solution, a substance that generates a hydroxide ion in an aqueous solution can be used without particular limitation, but among them, an aqueous solution of an oxide or hydroxide of an alkali metal and an aqueous solution of an oxide or hydroxide of an alkaline earth metal are preferably used.

The pH of the alkaline aqueous solution is sufficient if it is more than 7, but is preferably 9 or more, and more preferably 11 or more, but if it exceeds 12, it may corrode stainless steel, so it is preferably 11.5 or less. Examples of the alkaline aqueous solution include sodium hydroxide aqueous solution and potassium hydroxide aqueous solution.

As the alkaline aqueous solution, a phosphate can also be used, and it is preferable that the alkaline aqueous solution is at least one aqueous solution selected from the group consisting of phosphates, sodium hydroxide, and potassium hydroxide, and it is more preferable that the phosphate is used together with sodium hydroxide and potassium hydroxide. As the phosphate, dipotassium phosphate, tripotassium phosphate, pyrophosphate potassium, monosodium phosphate, disodium phosphate, trisodium phosphate, pyrophosphate sodium, tripotassium phosphate, metaphosphate sodium, etc. are mentioned. These can be used alone or in combination of two or more.

The concentration of sodium hydroxide and/or potassium hydroxide in the alkaline aqueous solution is usually 0.5 to 2% by mass, preferably 1 to 1.9% by mass, and when a phosphate is contained, the concentration of the phosphate in the alkaline aqueous solution is usually 5 to 15% by mass, and it is preferable to adjust the pH of the alkaline aqueous solution to 11.5 or less.

In addition, depending on the type of container, there are those that dissolve in strong alkali, so in that case, it is possible to use an aqueous solution of a weak acid alkali metal salt such as sodium carbonate, sodium hydrogen carbonate, sodium sulfite, sodium acetate, etc.

A preferred embodiment of the present invention is to perform the step of cleaning with an acidic aqueous solution and/or an alkaline aqueous solution (B) after the step of cleaning with a non-protonic solvent (A). Here, “sequentially” means that no other cleaning step is performed between the step of cleaning with a non-protonic solvent (A) and the step of cleaning with an acidic aqueous solution and/or an alkaline aqueous solution (B). That is, when two steps are performed sequentially, may be understood to mean that the steps are performed with no intervening cleaning steps between them.

<Step of cleaning with ultrapure water (C)> The step of cleaning with ultrapure water (ultrapure water cleaning step) (C) is performed after the step of cleaning with an acidic aqueous solution and/or an alkaline aqueous solution (B), and is a step of removing impurities and fine particles remaining in the apparatus. The cleaning liquid in the step of cleaning with ultrapure water (C) is ultrapure water having a resistivity of 17 MΩ·cm at 25° C. The resistivity of theoretical pure water is 18.24 MΩ·cm, but from the point of view of production efficiency, it is preferable for the resistivity of the water used in the methods of the present disclosure to be 17 MΩ·cm. The resistivity can be measured, for example, with a commercially available electrical conductivity meter.

The cleaning method, the number of cleaning times, the cleaning temperature, the amount of cleaning liquid used, etc. are the same as in the non-protonic solvent cleaning step (A). It is preferable to perform the step of cleaning with ultrapure water (C) in a clean room with a class 1000 level.

It is preferable that the step of cleaning with ultrapure water (C) is the final cleaning step.

It is preferable to perform the above cleaning step under an inert gas atmosphere such as nitrogen, argon, helium, etc. because there is a tendency that stannoxane compounds having Sn—O—Sn bonds are generated by hydrolysis of tin compounds and they are solidified and cleaning becomes difficult under atmospheric pressure.

### <Drying Step>

After the ultrapure water cleaning step (C), a step of drying the apparatus for a tin compound may be performed. The drying step may be performed by spraying or inserting an inert gas (pure nitrogen, etc.) at a chemical clean level. For example, in the case of nitrogen gas, it is performed by continuing to replace the gas in the apparatus with heated gas at 60° C. until the dew point temperature becomes −60° C. (7 ppm RH or less) to completely remove moisture.

<Apparatus for a Tin Compound after Cleaning>

Embodiments of the disclosure also include an apparatus for a tin compound that has been cleaned by the cleaning method described herein. Since the apparatus for a tin compound of one embodiment of the present invention is highly purified, it is preferable to use it as a container for storing high-purity tin compounds after purification.

This storage container (not limited to a storage container, but including any apparatus for a tin compound that can store water) has the characteristic that when ultrapure water having a resistivity of 17 MΩ·cm at 25° C., which is used as a cleaning liquid in the ultrapure water cleaning step (C), is placed and left at 25° C. for 1 hour, the content of metal elements other than tin (for example, chromium (Cr), iron (Fe), magnesium (Mg), nickel (Ni), sodium (Na), molybdenum (Mo), potassium (K), etc.) is each 1.5 mass ppb or less. The content of each element is more preferably 1 mass ppb or less, further preferably 0.3 mass ppb or less, and particularly preferably 0.3 mass ppb or less. That is, the water after being placed in the container is barely contaminated even after being placed in the container relative to its purity prior to being put in the container.

In addition, it is preferable that the increase in the amount of halogen ions in the water is 100 mass ppb or less, and the increase in the amount of particles with a particle size of 0.5 m or more is 100/mL or less.

It is preferable that the increase in the amount of halogen ions is 50 mass ppb or less, and it is more preferable that it is 30 mass ppb or less. It is preferable that the increase in the amount of particles with a particle size of 0.5 m or more is 50/mL or less, and it is more preferable that it is 10/mL or less. In addition, it is preferable that the increase in the amount of metal elements is each 1.0 mass ppb or less for the above metal elements other than tin.

The method for quantifying halogen ions and metal elements, as well as the method for measuring the number of particles with a diameter of 0.5 μm or larger, will be described later in the examples.

Since the apparatus for a tin compound of the present embodiment is highly purified, as described above, even if the tin compound is stored, the tin compound is not significantly affected by impurities from the equipment and its purity does not decrease. For example, in the case of an apparatus for a tin compound, when the tin compound is placed in the storage container under an inert gas atmosphere, sealed, and stored at 45° C. for 3 months, the purity of the tin compound decreases by 0.1 mass % or less. As the inert gas, for example, argon, helium, nitrogen, etc. can be mentioned, and among them, nitrogen is preferable. In the case when the inert gas is nitrogen, it is preferable to set the oxygen concentration in the nitrogen atmosphere to 1 ppm or less (volume standard), and the dew point to −60° C. (7 ppm RH or less) or less because there is a tendency that the presence of oxygen and moisture leads to a decrease in the purity of the tin compound.

When the apparatus for a tin compound is a container, it is preferable that the container for storing high-purity tin compounds after purification has high sealing properties, and for example, in the above helium leak test, the amount of leaking helium is usually 5×10⁻⁹ Pa·m³/s or less, and preferably 1×10⁻⁹ Pa·m³/s or less.

### [Helium Leak Test]

It is preferable to perform the leak test after the drying step, and it is performed as follows (I) and (II).

(I) After purging the apparatus for a tin compound with helium multiple times (usually 2 times, preferably 3 times) through an air-operated valve, fill the apparatus with helium to 345 kPa and keep it for 4 hours to confirm that there is no leakage.

(II) In the case where the above apparatus is a container, after completely drying the container once in a vacuum state (vacuum drying), fill the container with helium to 34.5 kPa and connect a helium detector with a VCR® and a KF adapter manufactured by Cosmo Tech Co., Ltd. Check the valve seat leakage amount. For example, the valve seat leakage can be checked at a metal gasket type connector part.

There is no particular restriction on the capacity of the container, but considering that there are cases where it is used in conjunction with other apparatuses and transported, 100 mL to 300 L is preferable.

### EXAMPLES

The present invention will be described below with reference to examples, but the present invention is not limited to the following examples as long as it does not exceed the gist of the present invention. Note that “%” in the examples means mass standard.

The quantitative method of halogen ions, the measurement method of the number of particles, and the quantitative method of metal elements are as follows, and usually, after filling the container with ultrapure water, measurement is performed on the filled ultrapure water. In addition, the purity measurement method of isopropyltris(dimethylamino)tin is as follows.

### [Quantitative Method of Halogen Ions]

Ion chromatography (manufactured by Dionex Corporation, “ISC-3000”) was used.

[Measurement Method of the Number of Particles with a Particle Size of 0.5 μm or More]

The number of particles with a particle size of 0.5 μm or more was measured using a particle counter utilizing laser light scattering (manufactured by Particle Measuring Systems (PMS) Co., Ltd., “AZ-SO2/LS-200”).

### [Quantitative Method of Metal Elements]

Quantitative analysis of metal elements was performed using ICP-MS (high-frequency emission mass spectrometer, manufactured by Agilent Technologies, “Agilent7700”).

[Purity of isopropyltris(dimethylamino)tin]

About 1 g of isopropyltris(dimethylamino)tin was weighed and placed in an NMR tube with an inner diameter of 5 mm, and quantitative analysis was performed using a ¹¹⁹Sn-NMR spectrum. Note that the purity is in terms of tin atoms (mol %). The apparatus and conditions used are as follows.

Measuring instrument: JNM ECZ-400 (manufactured by Japan Electron Co., Ltd.)

### Example 1

First, the following container, ultrapure water, and tin compound were prepared, and after placing the tin compound in the container and taking it out, a used container was prepared as follows.

### (Container)

The cleaning was performed for a container with a capacity of 1 L that can be sealed. The material of the container is SUS316L. On the ceiling of the container, in addition to the valve (1) of the dip tube whose tube extends to the bottom of the container, two other valves (2 and 3) are provided, and each of them is a three-way valve.

These three three-way valves are connected to two of the gas supply port (nitrogen or rare gas), the supply port of the cleaning liquid (cleaning liquid of each step (A) to (C)), and the discharge port of the waste liquid container for cleaning after the container is connected.

### (Ultrapure Water)

Ultrapure water was supplied as electrical deionized water (EDI water: Electro Deionization water) from a small ultrapure water production apparatus “Arium®” manufactured by Sartorius.

### (Tin Compound)

Isopropyltris(dimethylamino)tin (purity 99.8 mol %) was prepared.

### (Contact Between Tin Compound and Container)

The above-mentioned container that had been cleaned was prepared, and at least 8 hours were spent drying by flowing heated nitrogen at about 60° C. until the dew point temperature became −60° C. or less. In a clean room, isopropyltris(dimethylamino)tin was filled into the container, left for 24 hours, and then isopropyltris(dimethylamino)tin was taken out of the container.

### ˜Apparatus Cleaning˜

[Cleaning with Non-Protonic Solvent (First Time)]

n-Heptane was prepared. Then, in a simple glove box with an oxygen concentration of 1 ppm or less, n-heptane was injected from valves 2 and 3 and it was confirmed that the waste liquid container overflowed from valve 1 (i.e., it was confirmed that the container was filled with n-heptane), and injection was stopped.

Then, valve 1 was changed to flow to the waste liquid container side, valves 2 and 3 were changed to the gas supply direction, and while supplying nitrogen gas from valves 2 and valve 3, n-heptane was discarded to the waste liquid container through valve 1.

[Cleaning with Non-Protonic Solvent (Repeated)]

This step was repeated twice with about 1.2 L of n-heptane per cycle, and after emptying the container, valve 1 of the dip tube was changed to the solvent supply side, and valves 2 and 3 were changed to the waste liquid container side.

[Cleaning with Acidic Aqueous Solution (First Time)]

A 10% nitric acid aqueous solution (pH 0) was prepared using electrical deionized water and concentrated nitric acid, and a 10% nitric acid aqueous solution was injected from the dip tube valve 1, and nitric acid aqueous solution was injected until the solution overflowed from valves 2 and 3. Then, the direction of the dip tube valve 1 was changed to the waste liquid container side, and valves 2 and 3 were changed to the gas supply side, and while supplying nitrogen gas from valves 2 and 3, all the 10% nitric acid aqueous solution was discharged to the waste liquid container through valve 1.

[Cleaning with Acidic Aqueous Solution (Repeated)]

The cycle of cleaning with the above 10% nitric acid aqueous solution was repeated twice with about 1.2 L of 10% nitric acid aqueous solution per cycle. When the container was empty, the dip tube valve 1 was changed to the solvent receiving direction, and valves 2 and 3 were changed to the waste liquid container side.

[Cleaning with Ultrapure Water]

Ultrapure water (electrical deionized water) was injected through the dip tube valve 1 and discharged from valves 2 and 3.

The electrical deionized water discharged was measured for water purity using a resistivity meter. Electrical deionized water was continued to be flowed until the resistivity reached at least 17.0 MΩ·cm. In the usual case, 8 to 10 L of electrical deionized water was flowed.

The dip tube valve 1 was changed to the waste liquid container side, and valves 2 and 3 were changed to the gas supply side, and nitrogen was injected into valves 2 and 3 to discharge all the electrical deionized water through valve 1 to the waste liquid container.

### [Borescope Visual Inspection]

In a clean room, a borescope was inserted from each valve of the container to confirm whether solid residues were attached to the surface. If solid residues were observed, the nitric acid cleaning step was repeated until the visual inspection passed. In this embodiment, solid residues were not observed.

### [Drying Step]

If the visual inspection passed, the dip tube valve 1 was connected to the heated nitrogen supply side, and valves 2 and 3 were connected to the vent in the form of passing through the dew point meter.

Nitrogen at 60° C. was supplied from valve 1 and flowed until the dew point became −60° C. or less. In the usual case, it was continued to be flowed for at least 8 hours.

### [Measurement Results]

### (Quantitative Analysis of Metal Elements)

Quantitative analysis of metal elements was performed on the ultrapure water filled in the container after the cleaning and other steps, and the results are shown in Table 1 below.

From Table 1 below, the content of metal elements was 1.5 mass ppb or less for all. In addition, as a result of observing the inside of the container with a borescope, no precipitates were observed.

TABLE 1

(mass ppb)

| Na | Mg | K | Cr | Fe | Ni | Mo |
|---|---|---|---|---|---|---|
| 0.02 | 0.03 | 0.01 | 0.02 | 0.04 | 0.03 | 0.02 |

### (Helium Leak Measurement)

After cleaning and drying the tin compound storage container, the following experiment was performed in a clean zone to confirm the airtightness. Helium was filled into the container through an air-operated valve, and helium purging work was performed three times, and then helium was filled until it became 345 kPa. It was confirmed that there was no leakage for 4 hours thereafter.

The tin compound storage container was completely dried by vacuum attraction for 24 hours at 60° C., then returned to 25° C., and then vacuum attraction was performed again, and helium was inhaled until it became 34.5 kPa.

The leak from the VCR (valve seat) was measured using a helium detector connected with a VCR® and a KF adapter manufactured by Cosmo Tech Co., Ltd., and the result was 5×10⁻¹⁰ Pa·m³/s.

(Purity of Tin Compound after Storage)

When isopropyltris(dimethylamino)tin was placed in the above apparatus for a tin compound, sealed under an inert gas atmosphere (argon), and stored at 25° C. for 1 month, the purity of the tin compound decreased by about 0.01 mass % in the purity measurement of isopropyltris(dimethylamino)tin described above, and it was found that it hardly decreased.

### Example 2

Isopropyltris(dimethylamino)tin (purity 99.8 mol %) was prepared.

As a storage container for this, a 1000 mL container made of SUS316L was prepared. In a glove box under a nitrogen atmosphere, isopropyltris(dimethylamino)tin was filled into the storage container, left for 24 hours, and then isopropyltris(dimethylamino)tin was taken out of the container and the container was dried.

[Cleaning with Non-Protonic Solvent]

n-Heptane was prepared, and the storage container was cleaned by rinsing in a simple glove box under a nitrogen atmosphere with an oxygen concentration of 1 ppm or less, and the non-protonic solvent cleaning step was performed. Rinsing was performed three times with 400 mL.

[Cleaning with Alcohol]

Methanol with a moisture content of 10 ppm or less was prepared, and the storage container was cleaned by rinsing in a simple glove box under a nitrogen atmosphere, and the alcohol cleaning step was performed. Rinsing was performed three times with 400 mL.

### [Drying]

The drying step was performed by spraying and inserting pure nitrogen gas at a chemical clean level heated to 60° C.

[Cleaning with Acidic Aqueous Solution]

A 10% nitric acid aqueous solution was prepared as the acidic aqueous solution, and the storage container was cleaned by rinsing in a simple glove box under a nitrogen atmosphere with an oxygen concentration of 0.1 volume % or less, and the acidic aqueous solution cleaning step was performed. Rinsing was performed twice with 400 mL.

[Cleaning with Ultrapure Water]

Ultrapure water (25° C. resistivity: 17 MΩ·cm or more) was prepared, and the storage container was cleaned by rinsing in a simple glove box under a nitrogen atmosphere, and the ultrapure water cleaning step was performed. Rinsing was performed three times with 400 mL.

### [Measurement Results]

### (Quantitative Analysis of Halogen Ions and Measurement of the Number of Particles)

Ultrapure water (25° C. resistivity: 17 MΩ·cm or more) was filled into the storage container after the cleaning and other steps, sealed, and left at 25° C. for 1 hour. Quantitative analysis of halogen ions and measurement of the number of particles were performed on the filled ultrapure water.

As a result, the increase in the amount of halogen ions compared to the ultrapure water before filling was 50 mass ppb, and the increase in the amount of particles with a particle size of 0.5 μm or more was 30/mL.

### (Quantitative Analysis of Metal Elements)

Quantitative analysis of metal elements was performed on the filled ultrapure water, and the results are shown in Table 2 below.

From Table 2 below, the content of metal elements was 1.5 mass ppb or less for all. In addition, as a result of observing the inside of the container with a borescope, no precipitates were observed.

TABLE 2

(mass ppb)

| Na | Mg | K | Cr | Fe | Ni | Mo |
|---|---|---|---|---|---|---|
| 0.01 | 0.01 | 0.02 | 0.02 | 0.05 | 0.04 | 0.01 |

### (Helium Leak Measurement)

After cleaning and drying the tin compound storage container, the following experiment was performed in a clean zone to confirm the airtightness. Helium was filled into the container through an air-operated valve, and helium purging work was performed three times, and then helium was filled until it became 345 kPa. It was confirmed that there was no leakage for 4 hours thereafter.

The tin compound storage container was completely dried by vacuum attraction for 24 hours at 60° C., then returned to 25° C., and then vacuum attraction was performed again, and helium was inhaled until it became 34.5 kPa.

The leak from the VCR (valve seat) was measured using a helium detector connected with a VCR® and a KF adapter manufactured by Cosmo Tech Co., Ltd., and the result was 5×10⁻¹⁰ Pa·m³/s.

Note that when alcohol and nitric acid react, there is a possibility that explosive nitric esters will be generated, so when cleaning with nitric acid after alcohol cleaning, it is necessary to perform it after sufficiently drying the alcohol or sufficiently removing the alcohol with ultrapure water or the like.

(Purity of Tin Compound after Storage)

When isopropyltris(dimethylamino)tin was placed in the above apparatus for a tin compound, sealed under an inert gas atmosphere (argon), and stored at 25° C. for 1 month, the purity of the tin compound decreased by about 0.01 mass % in the purity measurement of isopropyltris(dimethylamino)tin described above, and it was found that it hardly decreased.

### Example 3

Isopropyltris(dimethylamino)tin (purity 99.8 mol %) was prepared.

As a storage container for this, a 1000 mL container made of SUS316L was prepared. In a glove box under a nitrogen atmosphere, isopropyltris(dimethylamino)tin was filled into the storage container, left for 24 hours, and then isopropyltris(dimethylamino)tin was taken out of the container and the container was dried.

[Cleaning with Non-Protonic Solvent]

n-Heptane was prepared, and the storage container was cleaned by rinsing in a simple glove box under a nitrogen atmosphere with an oxygen concentration of 0.1 volume % or less, and the non-protonic solvent cleaning step was performed. Rinsing was performed three times with 400 mL.

### [Drying]

The drying step was performed by spraying and inserting pure nitrogen gas at a chemical clean level heated to 60° C.

[Cleaning with Alkaline Aqueous Solution]

A 1.8% sodium hydroxide aqueous solution (pH 13.7) was prepared as the alkaline aqueous solution, and the storage container was cleaned by rinsing in a simple glove box under a nitrogen atmosphere with an oxygen concentration of 0.1 volume % or less, and the alkaline aqueous solution cleaning step was performed. Rinsing was performed three times with 400 mL each time.

[Cleaning with Ultrapure Water]

Ultrapure water (25° C. resistivity: 17 MΩ·cm) was prepared, and the storage container was cleaned by rinsing in a simple glove box under a nitrogen atmosphere, and the ultrapure water cleaning step was performed. Rinsing was performed three times with 400 mL each time.

### [Measurement Results]

### (Quantitative Analysis of Halogen Ions and Measurement of the Number of Particles)

Ultrapure water (25° C. resistivity: 17 MΩ·cm) was filled into the storage container after the cleaning and other steps, sealed, and left at 25° C. for 1 hour. Quantitative analysis of halogen ions and measurement of the number of particles were performed on the filled ultrapure water.

As a result, the increase in the amount of halogen ions compared to the ultrapure water before filling was 24 mass ppb, and the increase in the amount of particles with a particle size of 0.5 μm or more was 3/mL.

### (Quantitative Analysis of Metal Elements)

The metal elements in the filled ultrapure water were quantified using ICP-MS, and the results are shown in Table 3 below.

From Table 3 below, the content of metal elements was 1.5 mass ppb or less for all. In addition, as a result of observing the inside of the container with a borescope, no yellow-tinged precipitates were observed at all.

TABLE 3
(mass ppb)

| Na | Mg | K | Cr | Fe | Ni |
|---|---|---|---|---|---|
| 0.02 | 0.03 | 0.03 | 0.05 | 0.12 | 0.10 |

### (Helium Leak Measurement)

After cleaning and drying the tin compound storage container, the following experiment was performed in a clean zone to confirm the airtightness. Helium was filled into the container through an air-operated valve, and helium purging work was performed three times, and then helium was filled until it became 345 kPa. It was confirmed that there was no leakage for 4 hours thereafter.

The tin compound storage container was completely dried by vacuum attraction for 24 hours at 60° C., then returned to 25° C., and then vacuum attraction was performed again, and helium was inhaled until it became 34.5 kPa.

The leak from the VCR (valve seat) was measured using a helium detector connected with a VCR® and a KF adapter manufactured by Cosmo Tech Co., Ltd., and the result was 5×10⁻¹⁰ Pa·m³/s.

(Purity of Tin Compound after Storage)

When isopropyltris(dimethylamino)tin was placed in the above apparatus for a tin compound, sealed under an inert gas atmosphere (nitrogen), and stored at 25° C. for 1 month, the purity of the tin compound decreased by about 0.01 mass % in the purity measurement of isopropyltris(dimethylamino)tin described above, and it was found that it hardly decreased.

### Comparative Example 1: Acid Cleaning⇒Pure Water Cleaning⇒Alkaline Cleaning⇒Pure Water Cleaning⇒Drying

Isopropyltris(dimethylamino)tin (purity 99.8 mol %) was prepared. As a storage container for this, a 1000 mL container made of SUS316L was prepared. In a glove box under a nitrogen atmosphere, isopropyltris(dimethylamino)tin was filled into the storage container, left for 24 hours, and then isopropyltris(dimethylamino)tin was taken out of the container and the container was dried.

[Cleaning with Acidic Aqueous Solution]

A 10% nitric acid aqueous solution was prepared as the acidic aqueous solution, and the storage container was cleaned by rinsing in a simple glove box under a nitrogen atmosphere with an oxygen concentration of 0.1 volume % or less, and the acidic aqueous solution cleaning step was performed. Rinsing was performed once with 400 mL. When the 10% nitric acid aqueous solution was inserted for the first time, brown gas (nitrogen oxide) was generated and precipitates were generated, so rinsing was performed only once.

[Cleaning with Ultrapure Water]

Ultrapure water (25° C. resistivity: 17 MΩ·cm) was prepared, and the storage container was cleaned by rinsing in a simple glove box under a nitrogen atmosphere, and the ultrapure water cleaning step was performed. Rinsing was performed three times with 400 mL each time.

[Cleaning with Alkaline Aqueous Solution]

A 1.8% sodium hydroxide aqueous solution was prepared as the alkaline aqueous solution, and the storage container was cleaned by rinsing in a simple glove box under a nitrogen atmosphere with an oxygen concentration of 0.1 volume % or less, and the alkaline aqueous solution cleaning step was performed. Rinsing was performed three times with 400 mL each time.

[Cleaning with Ultrapure Water]

Ultrapure water (25° C. resistivity: 17 MΩ·cm) was prepared, and the storage container was cleaned by rinsing in a simple glove box under a nitrogen atmosphere, and the ultrapure water cleaning step was performed. Rinsing was performed three times with 400 mL each time.

### [Drying]

The drying step was performed by spraying and inserting pure nitrogen gas at a chemical clean level heated to 60° C.

### [Measurement Results]

The storage container after the cleaning and other steps was used, and the inside was confirmed with a borescope, and slight deposits were observed. Since deposits were observed by visual inspection, it is clear that it is not a satisfactory cleaning without performing other measurements.

### Example 4

First, the container, ultrapure water, and tin compound were prepared in the same manner as in Example 1, and after placing the tin compound in the container and taking it out, a used container was prepared.

### ˜Apparatus Cleaning˜

[Cleaning with Non-Protonic Solvent (First Time)]

n-Hexane was prepared. Then, in a simple glove box with an oxygen concentration of 1 ppm or less, n-hexane was injected from valves 2 and 3 and it was confirmed that there was flow in the transparent tube connected to valve 1 (i.e., it was confirmed that the container was filled with n-hexane), and injection was stopped.

Then, valve 1 was changed to flow to the waste liquid container side, valves 2 and 3 were changed to the gas supply direction, and while supplying nitrogen gas from valves 2 and valve 3, n-hexane was discarded to the waste liquid container through valve 1.

[Cleaning with Non-Protonic Solvent (Repeated)]

This step was repeated twice with about 1.2 L of n-hexane per cycle, and after emptying the container, valve 1 of the dip tube was changed to the solvent supply side, and valves 2 and 3 were changed to the waste liquid container side.

[Cleaning with Acidic Aqueous Solution (First Time)]

A 20% nitric acid aqueous solution (pH 0) was prepared using electrical deionized water and concentrated nitric acid, and a 20% nitric acid aqueous solution was injected from the dip tube valve 1, and nitric acid aqueous solution was injected until the solution overflowed from valves 2 and 3. Then, the direction of the dip tube valve 1 was changed to the waste liquid container side, and valves 2 and 3 were changed to the gas supply side, and while supplying nitrogen gas from valves 2 and 3, all the 20% nitric acid aqueous solution was discharged to the waste liquid container through valve 1.

[Cleaning with Acidic Aqueous Solution (Repeated)]

The cycle of cleaning with the above 20% nitric acid aqueous solution was repeated twice with about 1.2 L of 20% nitric acid aqueous solution per cycle. When the container was empty, the dip tube valve 1 was changed to the solvent receiving direction, and valves 2 and 3 were changed to the waste liquid container side.

[Cleaning with Ultrapure Water]

Ultrapure water (electrical deionized water) was injected through the dip tube valve 1 and discharged from valves 2 and 3.

The electrical deionized water discharged was measured for water purity using a resistivity meter. Electrical deionized water was continued to be flowed until the resistivity reached at least 17.0 MΩ·cm. In the usual case, 8 to 10 L of electrical deionized water was flowed.

The dip tube valve 1 was changed to the waste liquid container side, and valves 2 and 3 were changed to the gas supply side, and nitrogen was injected into valves 2 and 3 to discharge all the electrical deionized water through valve 1 to the waste liquid container.

### [Borescope Visual Inspection]

In a clean room, a borescope was inserted from each valve of the container to confirm whether solid residues were attached to the surface. If solid residues were observed, the nitric acid cleaning step was repeated until the visual inspection passed. In this embodiment, solid residues were not observed.

The present cleaning method can efficiently and highly purify an apparatus for a tin compound after synthesizing or storing the tin compound, and when synthesizing or storing the tin compound next time, it becomes possible to suppress the mixing and occurrence of impurities and fine particles. The tin compound synthesized or stored using the apparatus which has been highly purified by the present cleaning method is suitably used as a raw material for semiconductor and other applications.

In the above embodiments, specific embodiments of the present invention have been shown, but the above embodiments are merely examples, and are not intended to limit the present invention. Various modifications that are obvious to those skilled in the art are intended to be included in the scope of the present invention.

We claim:

1. A method for cleaning an apparatus that has been in contact with a tin compound having formula (1), the method comprising at least steps (A) to (C), wherein step (B) is performed after step (A), and step (C) is performed after step (B):
(A) a step of cleaning the apparatus with a non-protonic solvent,
(B) a step of cleaning the apparatus with an acidic aqueous solution and/or an alkaline aqueous solution, and
(C) a step of cleaning the apparatus with ultrapure water having a resistivity of 17 MΩ·cm at 25° C.;
RₚSnXₘ (1)
wherein R is a hydrocarbon group, p is an integer of 0 to 3, X is a hydrolyzable substituent, and m=4-p.

2. The method for cleaning an apparatus according to claim 1, wherein the step (A) is followed by performing the step (B) sequentially without any other intervening cleaning steps.

3. The method for cleaning an apparatus for a tin compound according to claim 1, further comprising after the step (A), performing a drying step and then performing the step (B) sequentially.

4. The method of cleaning the apparatus for a tin compound according to claim 1, wherein after the above step (A), a step of cleaning with alcohol and the drying step are performed, and then the above step (B) is performed sequentially.

5. The method for cleaning an apparatus for a tin compound according to claim 1, wherein the non-protonic solvent comprises at least one solvent selected from the group consisting of aromatic hydrocarbons, aliphatic hydrocarbons, esters, and ethers.

6. The method for cleaning an apparatus for a tin compound according to claim 1, wherein the acidic aqueous solution is a nitric acid aqueous solution with a concentration of 3 to 30% by mass.

7. The method for cleaning an apparatus for a tin compound according to claim 1, wherein a pH of the alkaline aqueous solution is 11.5 or less.

8. The method for cleaning an apparatus for a tin compound according to claim 1, wherein the alkaline aqueous solution is at least one solution selected from the group consisting of a phosphate solution, a sodium hydroxide solution, and a potassium hydroxide solution.

9. The method for cleaning an apparatus for a tin compound according to claim 8, wherein a concentration of sodium hydroxide and/or potassium hydroxide is 0.5 to 2% by mass.

10. The method for cleaning an apparatus for a tin compound according to claim 1, further comprising performing a drying step after the step (C).

11. The method for cleaning an apparatus for a tin compound according to claim 1, wherein a value of p in the formula (1) is 0 or 1.

12. The method for cleaning an apparatus for a tin compound according to claim 1, wherein the tin compound having formula (1) is at least one selected from the group consisting of t-butyltris(dimethylamino)tin, n-butyltris(dimethylamino)tin, t-butyltris(diethylamino)tin, di-t-butylbis(dimethylamino)tin, sec-butyltris(dimethylamino)tin, n-pentyltris(dimethylamino)tin, isobutyltris(dimethylamino)tin, isopropyltris(dimethylamino)tin, t-butyltri-t-butoxytin, n-butyltri-t-butoxytin, isopropyltri-t-butoxytin, isopropyltri-t-amyloxytin, t-butyltri-t-amyloxytin, tetra-t-butoxytin, tetrakis(dimethylamino) tin, 1-methyl-1-cyclopentyltris(dimethylamino)tin, and 1-methyl-1-cyclopentyltri-t-butoxytin.

13. An apparatus for a tin compound that has been in contact with the tin compound having formula (1) and has been cleaned by the cleaning method according to claim 1.

14. The apparatus for a tin compound according to claim 13, which is a container for storing tin compounds.

15. The apparatus for a tin compound according to claim 13, wherein when ultrapure water having a resistivity of 17 MΩ·cm at 25° C. is filled into the apparatus and left at 25° C. for 1 hour, a content of each metal element sodium, potassium, magnesium, iron, chromium, and nickel is 1.5 mass ppb or less.

16. The apparatus for a tin compound according to claim 13, wherein when ultrapure water with a resistivity of 17 MΩ·cm at 25° C. is filled into the apparatus and left at 25° C. for 1 hour, an increase in halogen ion concentration in the water is 100 mass ppb or less and an increase in a number of particles with a diameter of 0.5 μm or more is 100 particles/mL or less.

17. The apparatus for a tin compound according to claim 13, wherein when the tin compound having formula (1) is placed in the apparatus, sealed under an inert gas atmosphere, and stored at 25° C. for one month, a decrease in the purity of the tin compound is 0.1 mass % or less.

18. The apparatus for a tin compound according to claim 13, wherein when the apparatus is vacuum-dried and then filled with helium at 34.5 kPa, an amount of helium leaking from the joint part is 5×10⁻⁹ Pa·m³/s or less as measured by a helium detector.

19. The apparatus for a tin compound according to claim 15, which is a container for storing tin compounds.

20. A pattern forming method for a semiconductor, including a step of depositing a tin compound having formula (1) on a substrate using an apparatus that has been in contact with the tin compound having formula (1) to obtain a thin film, a step of exposing the thin film to radiation, and a step of developing the exposed thin film, wherein the apparatus is a tin compound storage container in which when ultrapure water having a resistivity of 17 MΩ·cm at 25° C. is filled into the apparatus and left at 25° C. for 1 hour, the content of each metal element sodium, potassium, magnesium, iron, chromium, and nickel is 1.5 mass ppb or less:
RₚSnXₘ (1)
wherein R is a hydrocarbon group, p is an integer of 1 to 3, X is a hydrolyzable substituent, and m=4-p.
